(19) United States
(12) Patent Application Publication
(10) Pub. No.: US 2014/0159105 A1
(43) Pub. Date: Jun. 12, 2014

(54) POWER SEMICONDUCTOR DEVICE

(71) Applicant: SAMSUNG ELECTRO-MECHANICS CO., LTD., Suwon (KR)

(72) Inventors: Kee Ju Um, Suwon (KR); In Hyuk Song, Suwon (KR); Chang Su Jang, Suwon (KR); Jae Hoon Park, Suwon (KR); Dong Soo Seo, Suwon (KR)

(73) Assignee: SAMSUNG ELECTRO-MECHANICS CO., LTD., Suwon (KR)

(21) Appl. No.: 13/831,780

(22) Filed: Mar. 15, 2013

(30) Foreign Application Priority Data
Dec. 7, 2012 (KR) 10-2012-0142172

(51) Int. Cl. H01L 29/739

(52) U.S. Cl. CPC H01L 29/7397
USPC 257/139

(57) ABSTRACT

Disclosed herein is a power semiconductor device, including: a drift layer formed on the first surface of the semiconductor substrate, a well layer of a first conductive type, formed on the drift layer, a trench formed to reach the drift layer through the well layer, a first electrode formed in the trench, a second conductive type of second electrode region formed on the well layer, including a first region contacting the trench in a perpendicular direction and a second region spaced apart from the trench in a parallel direction and being perpendicular to the first region, a first conductive type of second electrode region formed to contact a side surface of the second conductive type of second electrode region, and a second electrode formed on the well layer and electrically connected to the second conductive type of second electrode region and the first conductive type of second electrode region.

### CROSS REFERENCE TO RELATED APPLICATION

This application claims the benefit of Korean Patent Application No. 10-2012-0142172, filed on Dec. 7, 2012, entitled “Power Semiconductor Device”, which is hereby incorporated by reference in its entirety into this application.

### BACKGROUND OF THE INVENTION

1. Technical Field

The present invention relates to a power semiconductor device.

2. Description of the Related Art

An insulated gate bipolar transistor (IGBT) has high input impedance of a field effect transistor and high power drive capability of a bipolar transistor, and thus, is mainly used as a power switching device.

The IGBT is broadly classified into a planar gate type IGBT and a trench type IGBT. Recently, the trench type IGBT that has a reduced size while still increasing current density has been developed and researched.

The short circuit ruggedness properties of the trench type IGBT are very important factors and thus have been developed thus far through many technological developments.

In this case, the most important point for improving the short circuit ruggedness properties is a method of controlling a channel length by modifying an emitter pattern, in which the channel length is controlled using a structure of the emitter pattern having a bar shape.

However, the emitter pattern structure is not appropriate for a trend towards reduction in a cell pitch. In this regard, as the cell pitch decreases, a ratio of an N+ emitter region needs to be reduced in order to satisfy the short circuit ruggedness of a constant level. However, in this case, a contact area between an emitter electrode and the N+ emitter region is reduced, abruptly increasing connection loss.

An IGBT according to the prior art is disclosed in U.S. Patent Laid-Open Publication No. 2011-180813.

### SUMMARY OF THE INVENTION

The present invention has been made in an effort to provide a power semiconductor device having a structure that easily controls a ratio of an N+ emitter region while still maintaining a contact area between an emitter electrode and the N+ emitter region.

Further, the present invention has been made in an effort to provide a power semiconductor device having a structure that is applicable to a wide cell pitch.

According to a first preferred embodiment of the present invention, there is provided a power semiconductor device including a semiconductor substrate of a first conductive type, having a first surface and a second surface, a drift layer of a second conductive type, formed on the first surface of the semiconductor substrate, a well layer of a first conductive type, formed on the drift layer, a trench formed to reach the drift layer through the well layer in a thickness direction, a first electrode formed in the trench, a second conductive type of second electrode region selectively formed on the well layer, including a first region contacting the trench in a perpendicular direction and a second region spaced apart from the trench in a parallel direction and being perpendicular to the first region, and having a higher concentration than the drift layer, a first conductive type of second electrode region formed on the well layer so as to contact a side surface of the second conductive type of second electrode region and having a higher concentration than the well layer, and a second electrode formed on the well layer and electrically connected to the second conductive type of second electrode region and the first conductive type of second electrode region.

In this case, the second conductive type of second electrode region may be formed with a ‘+’ shape based on a plane.

The second conductive type of the second electrode region may be formed such that a width of the second region, which is parallel to the trench, is greater than a width of the first region, which is parallel to the trench.

The second electrode may include a first surface facing the well layer and a second surface facing the first surface, and a contact portion protrudes on the first surface in a longitudinal direction so as to contact a second region of the second conductive type of the second electrode region and the first conductive type of the second electrode region.

The first conductive type may be a P type, and the second conductive type may be an N type.

The power semiconductor device may further include a second conductive type buffer layer formed between the semiconductor substrate and the drift layer and having a higher concentration than the drift layer.

The power semiconductor device may further include an insulating layer formed between an inner wall of the trench and the first electrode.

The power semiconductor device may further include an interlayer insulating layer formed over the trench.

The first electrode may be a gate electrode and the second electrode may be an emitter electrode.

The first electrode may be formed of poly silicon.

The power semiconductor device may further include a third electrode formed on the second surface of the semiconductor substrate.

In addition, the third electrode may be a collector electrode.

According to a second preferred embodiment of the present invention, there is provided a power semiconductor device including a semiconductor substrate of a first conductive type, having a first surface and a second surface, a drift layer of a second conductive type, formed on the first surface of the semiconductor substrate, a well layer of a first conductive type, formed on the drift layer, a trench formed to reach the drift layer through the well layer in a thickness direction, a first electrode formed in the trench, a second conductive type of second electrode region selectively formed on the well layer, including a first region contacting the trench in a perpendicular direction and a second region spaced apart from the trench in a parallel direction and being perpendicular to the first region, and having a higher concentration than the drift layer, a first conductive type of second electrode region formed on the well layer so as to surround a side surface of the second conductive type of second electrode region and having a higher concentration than the well layer, a second electrode formed on the well layer and electrically connected to the second conductive type of second electrode region and the first conductive type of second electrode region, and a third electrode formed on the second surface of the semiconductor substrate.

In this case, wherein the second conductive type of second electrode region is formed with a ‘+’ shape based on a plane.

The second conductive type of second electrode region may be formed such that a width of the second region, which is parallel to the trench, is greater than a width of the first region, which is parallel to the trench.

The first electrode may be a gate electrode, the second electrode may be an emitter electrode, and the third electrode may be a collector electrode.

In addition, the second electrode may include a first surface facing the well layer and a second surface facing the first surface, and a contact portion may protrude on the first surface in a longitudinal direction so as to contact a second region of the second conductive type of second electrode region and the first conductive type of second electrode region.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view of a power semiconductor device according to an embodiment of the present invention;

FIG. 2 is a cross-sectional view of the power semiconductor device 100 taken along a line A-A′ of FIG. 1;

FIG. 3 is a cross-sectional view of the power semiconductor device 100 taken along a line B-B′ of FIG. 1; and

FIG. 4 is a cross-sectional view of the power semiconductor device 100 taken along a line C-C′ of FIG. 1.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

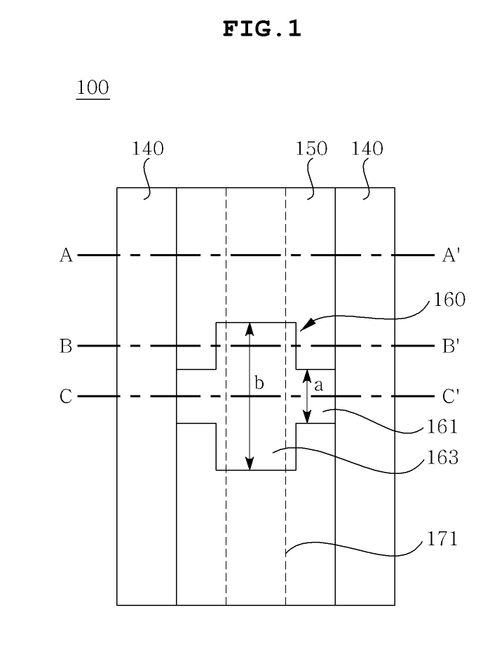

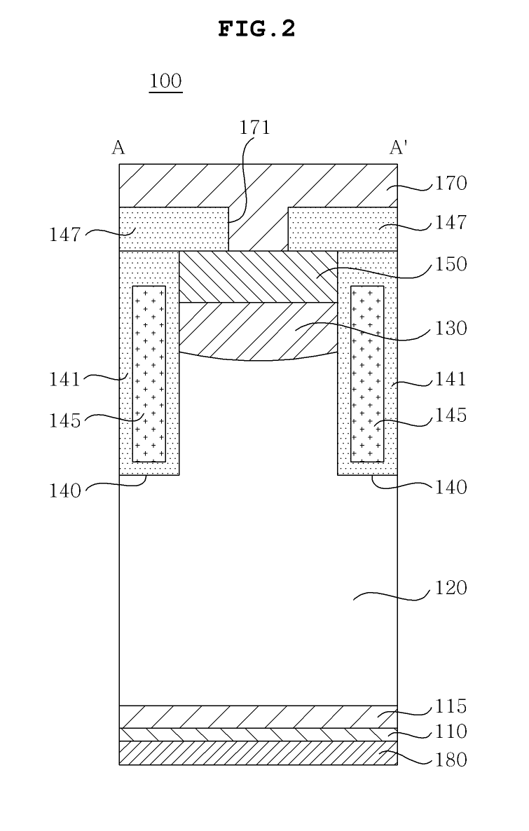

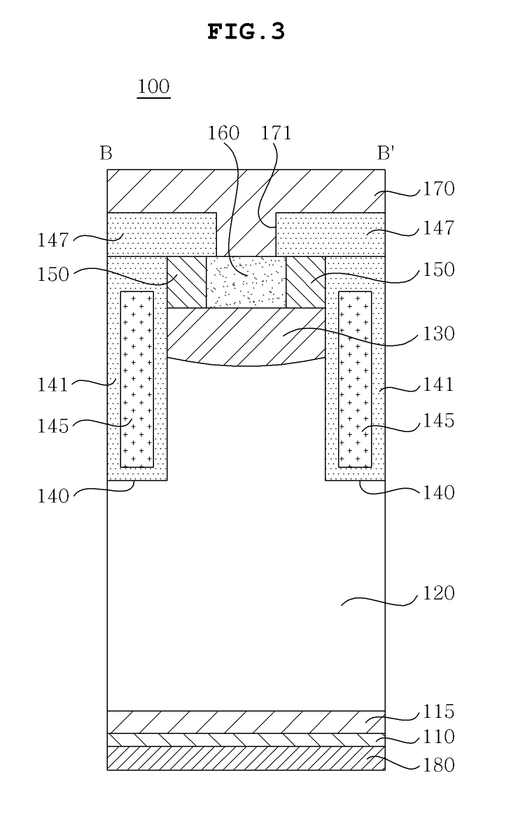

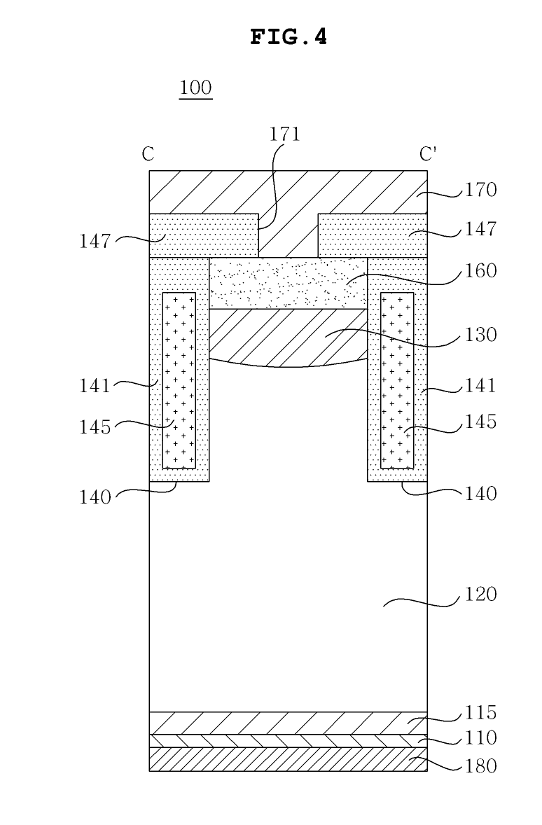

FIG. 1 is a plan view of a power semiconductor device 100 according to an embodiment of the present invention, FIG. 2 is a cross-sectional view of the power semiconductor device 100 taken along a line A-A′ of FIG. 1, FIG. 3 is a cross-sectional view of the power semiconductor device 100 taken along a line B-B′ of FIG. 1, and FIG. 4 is a cross-sectional view of the power semiconductor device 100 taken along a line C-C′ of FIG. 1.

Referring to FIGS. 1 through 4, the power semiconductor device 100 includes a first conductive type of semiconductor substrate 110, a drift layer 120 formed on the semiconductor substrate 110, a well layer 130 formed on the drift layer 120, a trench 140, a first electrode 145 formed in the trench 140, a first conductive type of second electrode region 150 and a second conductive type of second electrode region 160 which are formed on the well layer 130, and a second electrode 170 formed on the well layer 130. In FIG. 1, in order to clearly show the structures of the first conductive type of second electrode region 150 and the second conductive type of second electrode region 160, the second electrode 170 is omitted.

According to the present embodiment, the first conductive type of semiconductor substrate 110 may be formed of, but is not particularly limited to, a silicon wafer.

In addition, according to the present embodiment, the first conductive type may be, but is not particularly limited to, a P type.

The semiconductor substrate 110 has a first surface and a second surface. As shown in FIGS. 2 to 4, the drift layer 120, which is of a second conductive type, may be formed on the first surface and a third electrode 180 may be formed on the second surface.

In this case, the third electrode 180 may be a collector electrode and the semiconductor substrate 110 may function as a collector region.

According to the present embodiment, the drift layer 120, which is of a second conductive type, may be formed on a surface of the semiconductor substrate 110 using an epitaxial growth method. However, the present invention is not particularly limited thereto. Here, the second conductive type may be, but is not particularly limited to, an N type.

As shown in FIGS. 2 to 4, the power semiconductor device 100 may further include an N+ type of buffer layer 115 with a higher concentration than the drift layer 120, which is formed between the semiconductor substrate 110 of a P type and the drift layer 120 of an N type. In this case, the buffer layer 115 may also be formed using an epitaxial growth method. However, the present invention is not particularly limited thereto.

With regard to an insulated gate bipolar transistor (IGBT), the buffer layer 115 allows a reverse voltage to be applied between the drift layer 120 and the well layer 130 to prevent a depletion layer formed from a contact layer between the drift layer 120 and the well layer 130 from expanding to the semiconductor substrate 110 of a P type in a forward blocking mode in which a gate electrode and an emitter electrode short circuit and a positive voltage is applied from a collector electrode to the emitter electrode. Due to the buffer layer 115, the thickness of the drift layer 120 may be reduced, thereby reducing on-state losses in the power semiconductor device 100.

In a forward conduction mode (that is, when a predetermined voltage or more is applied to the gate to form a channel), as the concentration and thickness of the buffer layer 115 is increased, holes are further prevented from being injected from the semiconductor substrate 110 of a P type to the drift layer 120 of an N type, thereby increasing a switching speed of the power semiconductor device 100.

According to the present embodiment, the well layer 130 of a first conductive type may be formed on the drift layer 120.

Here, the first conductive type may be, but is not particularly limited to, a P type, as described above.

In this case, the well layer 130 of a P type may be formed by injecting P-type impurities into a surface of the drift layer 120 and expanding the P-type impurities in a depth direction. However, the present invention is not limited thereto.

According to the present embodiment, the trench 140 may be formed to reach the drift layer 120 through the well layer 130.

In detail, referring to FIGS. 2 to 4, the trench 140 may be formed to a predetermined depth so as to reach the drift layer 120 through the well layer 130 from a surface thereof in a thickness direction. In this case, a plurality of trenches 140 having the same depth and width may be formed at predetermined intervals. However, the present invention is not limited thereto.

Here, the term ‘the same’ does not mean the same dimension as mathematical meaning but refers to a substantially the same dimension in consideration of design errors, manufacture errors, measurement errors, and the like. Hereinafter, in this specification, the term ‘the same’ refers to a substantially the same dimension, as described above.

In this case, the trench 140 may be formed via an etch process using a mask. However, the present invention is not particularly limited thereto.

According to the present embodiment, an insulating layer 141 may be formed on an inner wall of the trench 140. Here, the insulating layer 141 may be, but is not limited to, an oxide layer formed using a thermal oxidation process.

The first electrode 145 formed in the trench 140 may be formed of, but is not limited to, poly silicon.

In this case, the first electrode 145 may be, but is not limited to, a gate electrode.

An interlayer insulating layer 147 may be formed over the trench 140 for electrical insulation between the first electrode 145 and the second electrode 170. Here, the interlayer insulating layer 147 may be formed of, but is not particularly limited to, boron phosphorus silicate glass (BPSG).

The power semiconductor device 100 may further include the first conductive type of second electrode region 150 and the second conductive type of second electrode region 160 which are formed on the well layer 130.

Here, the first conductive type and the second conductive type may be, but are not particularly limited to, a P type and an N type, respectively.

Portions of the first conductive type of second electrode region 150 and portions of the second conductive type of second electrode region 160 may directly contact contact portions 171 of the second electrode 170.

According to the present embodiment, the second conductive type of second electrode region 160 may be selectively formed on the well layer 130 and may include a first region 161 that contacts the trench 140 in a perpendicular direction thereto and a second region 163 that is spaced apart from the trench 140 in parallel thereto to be perpendicular to the first region 161, as shown in FIG. 1.

According to the present embodiment, the second conductive type of second electrode region 160 may be, but is not particularly limited to, an N+ type region having a higher concentration than the drift layer 120.

According to the present embodiment, the second conductive type of second electrode region 160 may be formed with a ‘+’ shape based on a plane, as shown in FIG. 1. However, the present invention is not particularly limited thereto.

Herein, the term ‘plane’ may refer to an upper surface of the power semiconductor device 100 viewed from above.

That is, the second conductive type of second electrode region 160 of the power semiconductor device 100 may be configured so that a width b (refer to FIG. 1) of the second region 163, which is measured in a direction parallel to the trench 140, may be greater than a width a (refer to FIG. 1) of the first region 161, which is measured in the direction parallel to the trench 140.

Due to this configuration, a contact area between the second electrode 170 and the second conductive type of the second electrode region 160 is increased, which will be described in detail below.

In the power semiconductor device 100, a surface area of the second conductive type of the second electrode region 160 may be the same as a surface area of the first conductive type of the second electrode region 150. However, the present invention is not limited thereto.

As shown in FIG. 1, the first conductive type of the second electrode region 150 of the power semiconductor device 100 is formed on the well layer 130 so as to contact a side surface of the second conductive type of the second electrode region 160, which is parallel to a thickness direction thereof.

Here, the term ‘thickness direction’ may correspond to the depth direction of the trench 140.

According to the present embodiment, the first conductive type of the second electrode region 150 may be, but is not particularly limited to, a P+ type region having a higher concentration than the well layer 130.

The second electrode 170 of the power semiconductor device 100 may be formed on the well layer 130 and may include a first surface facing the well layer 130 and a second surface facing the first surface and exposed to the outside.

In this case, the contact portions 171 may be formed on the first surface so as to be spaced apart from each other in a direction parallel to the trench 140 and may protrude in a longitudinal direction.

The contact portions 171 may contact the second region 163 of the second conductive type of second electrode region 160 and the first conductive type of second electrode region 150.

In more detail, the interlayer insulating layer 147 may be formed on the trench 140. In this case, a plurality of trenches 140 are spaced apart from each other, the interlayer insulating layer 147 formed on each of the trenches 140 may be formed to be spaced apart from an adjacent interlayer insulating layer 147.

Thus, the first conductive type of second electrode region 150 and the second conductive type of second electrode region 160 are exposed between the adjacent the interlayer insulating layers 147. In addition, the contact portions 171 of the second electrode 170 may be inserted between the adjacent interlayer insulating layers 147 to contact the exposed portions of the first conductive type of second electrode region 150 and the second conductive type of second electrode region 160.

Thus, portions of the second conductive type of second electrode region 160, which contact the contact portions 171 of the second electrode 170, are limited to a portion between the adjacent interlayer insulating layers 147.

Conventionally, in a power semiconductor device including an N+ emitter region and P+ emitter region having a bar shape, when an interval between trenches is reduced in order to reduce conduction loss to increase channel density, a contact area of the N+ emitter region, which contacts an emitter electrode, is reduced to increase contact resistance, thereby abruptly increasing conduction loss.

In order to overcome this problem, when an entire width of the N+ emitter region having a bar shape is increased, a ratio of the N+ emitter region to a P+ emitter region that contacts the trench is increased to increase peak current, thereby reducing the short circuit ruggedness.

When the ratio of the N+ emitter region to the P+ emitter region that contacts an emitter electrode is maintained constant and the entire width is increased, the length of a current path of to holes that extend below the N+ emitter region that contacts the trench is increased to increase latch-up resistance, thereby reducing short circuit ruggedness.

Accordingly, according to the present embodiment, as shown in FIG. 1, the width a of a portion of the second conductive type of second electrode region 160, which contacts the trench 140, is maintained and the width b of a portion of the second conductive type of second electrode region 160, which contacts the contact portions 171 of the second electrode 170 is increased. Thus, even if an interval between the trenches 140 is reduced, an area of a portion of the second conductive type of second electrode region 160, which contacts the second electrode 170, may be increased, and thus, a problem in terms of increase in contact resistance may be overcome.

In addition, a ratio of a portion of the second conductive type of second electrode region 160 to the first conductive type of second electrode region 150 which contacts the trench 140 may be maintained constant or reduced, thereby increasing short circuit ruggedness.

According to the present invention, the width of a portion of the N+ emitter region having a bar shape, which contacts a second electrode, is increased without change in the width of a portion which contacts a trench. Thus, even if an interval between trenches is reduced, an area of a portion of the N+ emitter region, which contacts the second electrode, may be increased, and thus, a problem in terms of increase in contact resistance may be overcome, thereby reducing conduction loss.

In addition, compared with a conventional power semiconductor device having a bar shape, a ratio of a portion of the N+ emitter region to a P+ emitter region which contacts the trench may be maintained or reduced, thereby increasing short circuit ruggedness.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A power semiconductor device comprising:
a semiconductor substrate of a first conductive type, having a first surface and a second surface;
a drift layer of a second conductive type, formed on the first surface of the semiconductor substrate;
a well layer of a first conductive type, formed on the drift layer;
a trench formed to reach the drift layer through the well layer in a thickness direction;
a first electrode formed in the trench;
a second conductive type of a second electrode region selectively formed on the well layer, including a first region contacting the trench in a perpendicular direction and a second region spaced apart from the trench in a parallel direction and being perpendicular to the first region, and having a higher concentration than the drift layer;
a first conductive type of a second electrode region formed on the well layer so as to contact a side surface of the second conductive type of second electrode region and having a higher concentration than the well layer; and
a second electrode formed on the well layer and electrically connected to the second conductive type of second electrode region and the first conductive type of second electrode region.

2. The power semiconductor device as set forth in claim 1, wherein the second conductive type of second electrode region is formed with a ‘+’ shape based on a plane.

3. The power semiconductor device as set forth in claim 1, wherein the second conductive type of second electrode region is formed such that a width of the second region, which is parallel to the trench, is greater than a width of the first region, which is parallel to the trench.

4. The power semiconductor device as set forth in claim 1, wherein the second electrode includes a first surface facing the well layer and a second surface facing the first surface, and a contact portion protrudes on the first surface in a longitudinal direction so as to contact a second region of the second conductive type of second electrode region and the first conductive type of second electrode region.

5. The power semiconductor device as set forth in claim 1, wherein the first conductive type is a P type, and the second conductive type is an N type.

6. The power semiconductor device as set forth in claim 1, further comprising a second conductive type buffer layer formed between the semiconductor substrate and the drift layer and having a higher concentration than the drift layer.

7. The power semiconductor device as set forth in claim 1, further comprising an insulating layer formed between an inner wall of the trench and the first electrode.

8. The power semiconductor device as set forth in claim 1, further comprising an interlayer insulating layer formed over the trench.

9. The power semiconductor device as set forth in claim 1, wherein the first electrode is a gate electrode and the second electrode is an emitter electrode.

10. The power semiconductor device as set forth in claim 1, wherein the first electrode is formed of poly silicon.

11. The power semiconductor device as set forth in claim 1, further comprising a third electrode formed on the second surface of the semiconductor substrate.

12. The power semiconductor device as set forth in claim 11, wherein the third electrode is a collector electrode.

13. A power semiconductor device comprising:
a semiconductor substrate of a first conductive type, having a first surface and a second surface;
a drift layer of a second conductive type, formed on the first surface of the semiconductor substrate;
a well layer of a first conductive type, formed on the drift layer;
a trench formed to reach the drift layer through the well layer in a thickness direction;
a first electrode formed in the trench;
a second conductive type of second electrode region selectively formed on the well layer, including a first region contacting the trench in a perpendicular direction and a second region spaced apart from the trench in a parallel direction and being perpendicular to the first region, and having a higher concentration than the drift layer;
a first conductive type of second electrode region formed on the well layer so as to surround a side surface of the second conductive type of second electrode region and having a higher concentration than the well layer;
a second electrode formed on the well layer and electrically connected to the second conductive type of second electrode region and the first conductive type of second electrode region; and
a third electrode formed on the second surface of the semiconductor substrate.

14. The power semiconductor device as set forth in claim 13, wherein the second conductive type of second electrode region is formed with a ‘+’ shape based on a plane.

15. The power semiconductor device as set forth in claim 13, wherein the second conductive type of second electrode region is formed such that a width of the second region, which is parallel to the trench, is greater than a width of the first region, which is parallel to the trench.

16. The power semiconductor device as set forth in claim 13, wherein the first electrode is a gate electrode, the second electrode is an emitter electrode, and the third electrode is a collector electrode.

17. The power semiconductor device as set forth in claim 13, wherein the second electrode includes a first surface facing the well layer and a second surface facing the first surface, and a contact portion protrudes on the first surface in a longitudinal direction so as to contact a second region of the second conductive type of second electrode region and the first conductive type of second electrode region.
